(19) United States
(12) Patent Application Publication
(10) Pub. No.: US 2018/0286725 A1
(43) Pub. Date: Oct. 4, 2018

(54) SUBSTRATE RETRAINER AND SUBSTRATE PROCESSING APPARATUS

(71) Applicant: HITACHI KOKUSAI ELECTRIC INC., Tokyo (JP)

(72) Inventors: Kazuki NONOMURA, Toyama-shi (JP); Hirohisa YAMAZAKI, Toyama-shi (JP)

(73) Assignee: HITACHI KOKUSAI ELECTRIC INC., Tokyo (JP)

(21) Appl. No.: 15/940,296

(22) Filed: Mar. 29, 2018

(30) Foreign Application Priority Data
Mar. 29, 2017 (JP) 2017-065174
Mar. 1, 2018 (JP) 2018-036095

(51) Int. Cl. H01L 21/673; C23C 16/458; C23C 16/52

(52) U.S. Cl. CPC H01L 21/67309; H01L 21/02189; C23C 16/52; C23C 16/4587

(57) ABSTRACT

Described is a technique capable of reducing an effect of a substrate retainer on a substrate processing while maintaining a strength of a substrate retainer. Provided is a substrate retainer configured to support a plurality of substrates in horizontal orientation with an interval therebetween, the substrate retainer including: main support columns; and auxiliary support columns, wherein: each main support columns is provided with a substrate support member configured to support a substrate; a diameter of each of the auxiliary support columns is larger than a diameter of each of the main support columns and smaller than a length of the substrate support member; a distance between an edge of the substrate and each of the auxiliary support columns is shorter than a distance between the edge of the substrate and each of the main support columns; and all of the auxiliary support columns are not in contact with the substrate.

### CROSS-REFERENCE TO RELATED PATENT APPLICATION

This non-provisional U.S. patent application claims priority under 35 U.S.C. § 119 of Japanese Patent Application No. 2017-065174, filed on Mar. 29, 2017 and Japanese Patent Application No. 2018-036095, filed on Mar. 1, 2018, the entire contents of which are hereby incorporated by reference.

### BACKGROUND

### 1. Field

The present disclosure relates to a substrate retainer and a substrate processing apparatus.

### 2. Description of the Related Art

Substrate that are to be processed by a vertical type semiconductor manufacturing apparatus are loaded into a process chamber thereof using a substrate retainer (also referred to as “boat”) capable of vertically supporting a plurality of substrates, and processed therein. During a substrate processing of the substrates by the semiconductor manufacturing apparatus, the substrate processing is affected by support columns of the substrate retainer. Therefore, deviation in the quality of the substrate processing may occur within the same substrate or the yield of the substrate processing may be degraded.

For example, in the conventional semiconductor manufacturing apparatus equipped with a vertical processing furnace, the support columns of the boat are in the proximity of the substrate (wafer). Thus, during the formation of a film, the film is also formed on the surface of the boat. Therefore, gas for forming the film is consumed by the boat and the concentration of the gas may be reduced about the boat. As the patterns become more miniaturized, the quality of the substrate may be degraded due to the consumption of the gas by the boat.

### SUMMARY

Described herein is a technique capable of reducing an effect of a substrate retainer on a substrate processing while maintaining a strength of substrate retainer.

According to one aspect of the technique described herein, there is provided a configuration configured to support a plurality of substrates in horizontal orientation with an interval therebetween, the configuration including: main support columns and auxiliary support columns, wherein: each of the main support columns is provided with a substrate support member configured to support a substrate; a diameter of each of the auxiliary support columns is larger than a diameter of each of the main support columns and smaller than a length of the substrate support member; a distance between an edge of the substrate and each of the auxiliary support columns is shorter than a distance between the edge of the substrate and each of the main support columns; and all of the auxiliary support columns are not in contact with the substrate.

### BRIEF DESCRIPTION OF THE DRAWINGS

FIG. 1 is a schematic view showing a vertical cross-section of a substrate processing apparatus according to an embodiment described herein.

FIG. 2 is a horizontal cross-section of the substrate processing apparatus taken along the line A-A in FIG. 1.

FIG. 3 is a block diagram showing a configuration of a controller of the substrate processing apparatus and components controlled by the controller according to the embodiment.

FIG. 4 is a flowchart illustrating a substrate processing for forming a zirconium oxide film using the substrate processing apparatus.

FIG. 5 is a timing diagram illustrating the substrate processing for forming the zirconium oxide film using the substrate processing apparatus.

FIG. 6 schematically illustrates a substrate retainer according to a first comparative example.

FIG. 7A schematically illustrates a substrate retainer according to the embodiment.

FIG. 7B is a perspective view of the substrate retainer according to the embodiment.

FIG. 8A is a side view of the substrate retainer according to the embodiment.

FIG. 8B schematically illustrates a cross-section of the substrate retainer taken along the line A-A′ in FIG. 8A.

FIG. 9 is a graph illustrating a comparison between decreases in thicknesses of films formed on surfaces of substrates according to the embodiment and the first comparative example of FIG. 6.

FIG. 10A schematically illustrates a substrate retainer according to a second comparative example.

FIG. 10B illustrates a relationship between support columns and the decrease in the thickness of the film formed on the surface of the substrate according to the second comparative example.

### DETAILED DESCRIPTION

<Configuration of Substrate Processing Apparatus>

Hereinafter, an embodiment will be described with reference to the drawings. In the following description, like reference numerals refer to like parts, and the description of the like parts may be omitted. For the convenience of description, features such as width, thickness and shape of each component shown in drawings may be schematically illustrated and may differ from those of actual component. However, the schematic illustrations of the components are examples and do not limit the interpretation of the features.

Hereinafter, a substrate processing apparatus according to the embodiment will be described with reference to the drawings. The substrate processing apparatus according to the embodiment may be a semiconductor manufacturing apparatus capable of performing film-forming process which is a substrate processing in the manufacturing of a semiconductor device such as an IC (Integrated Circuit).

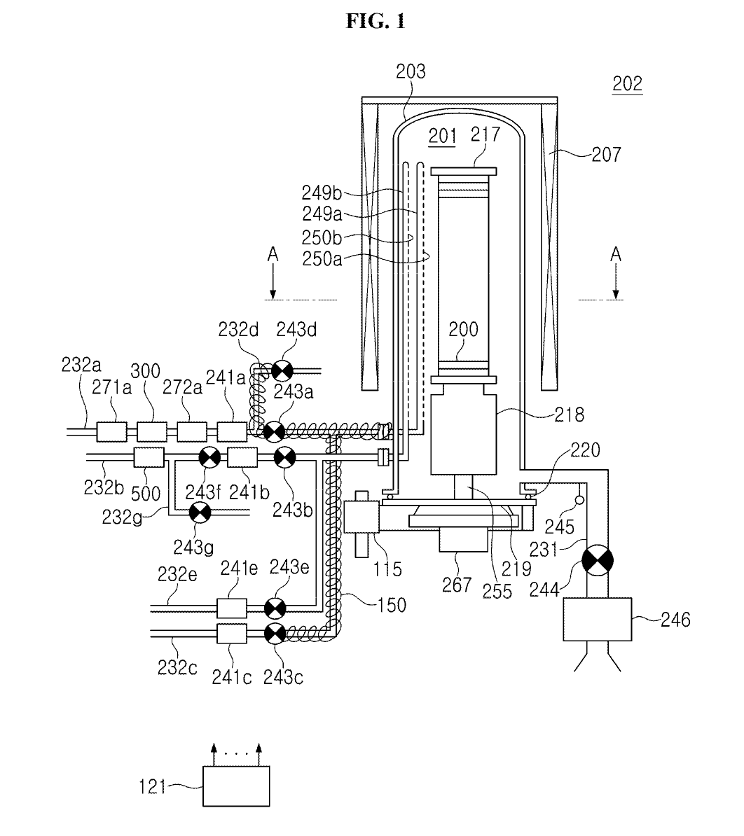

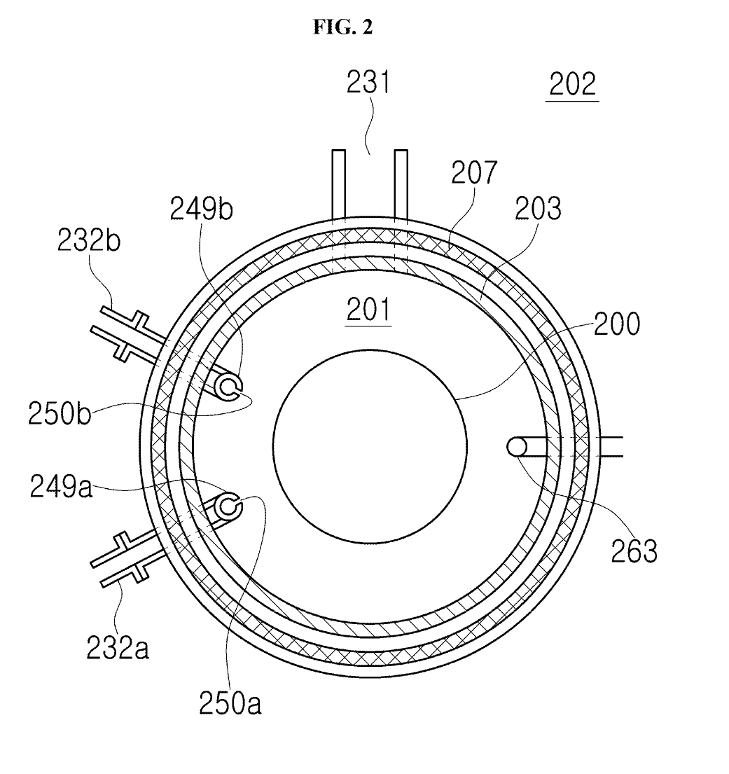

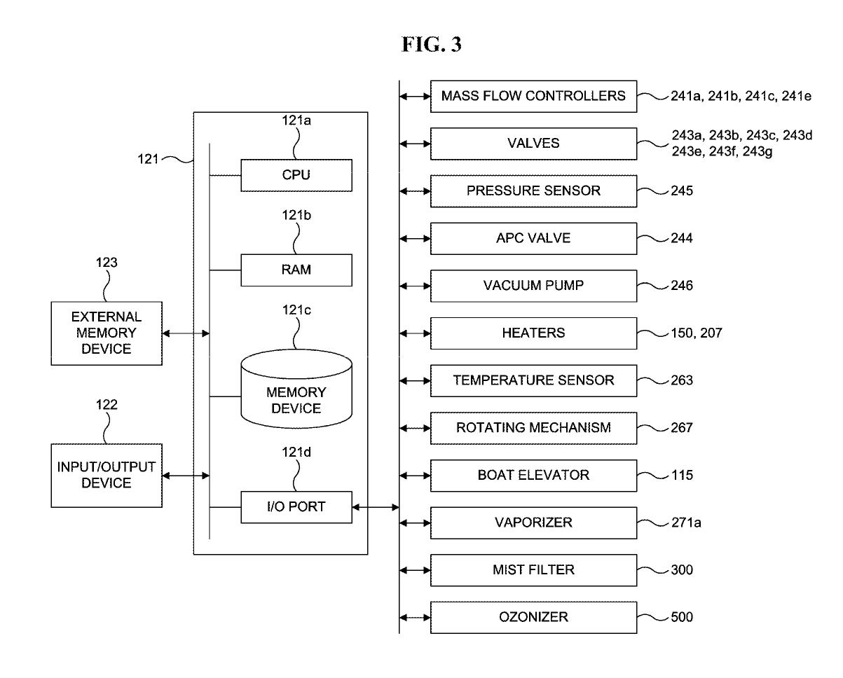

FIG. 1 schematically illustrates a vertical cross-section of a vertical type processing furnace 202 of the substrate processing apparatus according to the embodiment, FIG. 2 schematically illustrates a horizontal cross-section taken along the line A-A of the processing furnace 202 of the substrate processing apparatus shown in FIG. 1, and FIG. 3 is a block diagram schematically illustrating a configuration of a controller and components controlled by the controller of the substrate processing apparatus shown in FIG. 1.

As illustrated in FIG. 1, the processing furnace 202 includes a heater (heating mechanism or heating device) 207. The heater 207 is cylindrical, and vertically provided while being supported by a heater base (not shown) which is a support plate. A reaction tube 203 constituting a reaction vessel (processing vessel) is provided in and concentric with the heater 207.

A seal cap 219, which is a furnace opening cover capable of airtightly sealing the lower end opening of the reaction tube 203, is provided under the reaction tube 203. The seal cap 219 provided under the reaction tube 203 is in contact with the lower end of the reaction tube 203. An O-ring 220, which is a sealing member, is provided on the upper surface of the seal cap 219 and is in contact with the lower end of the reaction tube 203. A rotating mechanism 267 configured to rotate a boat 217 serving as a substrate retainer is provided at the seal cap 219 opposite to a process chamber 201.

A rotating shaft 255 of the rotating mechanism 267 is coupled to the boat 217 via the seal cap 219. As the rotating mechanism 267 rotates the boat 217, the wafers (substrates) 200 are rotated. The seal cap 219 may be moved upward/downward by a boat elevator 115, which is an elevating mechanism provided outside the reaction tube 203. The boat 217 may be loaded into the process chamber 201 or unloaded from the process chamber 201 by moving the seal cap 219 upward/downward by the boat elevator 115.

The boat (substrate retainer) 217 is provided on the seal cap 219 through a cap 218 which is an insulating member. The cap 218 is made of a heat-resistant material such as quartz and silicon carbide (SiC). The cap 218 provides support for the boat 217 as well as thermal insulation. The boat 217 is also made of a heat-resistant material such as quartz and SiC. The boat 217 supports concentrically arranged wafers 200 in vertical direction while each of the wafers 200 are in horizontal orientation. That is, the boat 217 supports, in multiple stages, concentrically arranged the wafers 200.

Nozzles 249a and 249b are provided in the process chamber 201 through sidewalls of the reaction tube 203. Gas supply pipes 232a and 232b are connected to the nozzles 249a and 249b, respectively. Thus, different gases may be supplied into the process chamber 201 by the two nozzles 249a and 249b and the two gas supply pipes 232a and 232b. As described later, inert gas supply pipes 232c and 232e are connected to the gas supply pipes 232a and 232b, respectively.

A vaporizer 271a, which is a vaporizing device (vaporizing means) capable of vaporizing a liquid source to obtain a source gas, a mist filter 300, a gas filter 272a, a mass flow controller (MFC) 241a which is a flow rate controller (flow rate control device) and a valve 243a which is an opening/closing valve are sequentially provided at the gas supply pipe 232a from the upstream side toward the downstream side of the gas supply pipe 232a. By opening the valve 243a, the source gas generated in the vaporizer 271a is supplied into the process chamber 201 via the nozzle 249a.

A ventilation line 232d connected to an exhaust pipe 231, which will be described later, is connected to the gas supply pipe 232a between the MFC 241a and the valve 243a. A valve 243d, which is an opening/closing valve, is provided at the ventilation line 232d. When the source gas described below is not supplied to the process chamber 201, the source gas is supplied to the ventilation line 232d via the valve 243d.

By closing the valve 243a and opening the valve 243d, the supply of the source gas into the process chamber 201 may be stopped even when the source gas is continuously generated by the vaporizer 271a. A certain amount of time is required to stably generate the source gas. The operation of the valve 243a and the valve 243d reduces the time required for switching between the supply of the source gas into the process chamber 201 and the suspending of the supply of the source gas.

The inert gas supply pipe 232c is connected to the downstream side of the valve 243a at the gas supply pipe 232a. A mass flow controller (MFC) 241c which is a flow rate controller (flow rate control device) and a valve 243c which is an opening/closing valve are provided at the inert gas supply pipe 232c in order from the upstream side toward the downstream side of the inert gas supply pipe 232c. A heater 150 is provided at the gas supply pipe 232a, the inert gas supply pipe 232c and the ventilation line 232d to prevent re-liquefaction of the source gas.

The above-described nozzle 249a is connected to the front end portion of the gas supply pipe 232a. The nozzle 249a is provided in an annular space between the inner wall surface of the reaction tube 203 and the wafers 200, and extends from bottom to top of the inner wall of the reaction tube 203 along the stacking direction of the wafers 200. For example, the nozzle 249a includes an L-shaped long nozzle.

A plurality of gas supply holes 250a for supplying gases is provided at a side surface of the nozzle 249a. The gas supply holes 250a are open toward the center of the reaction tube 203. The gas supply holes 250a are provided at the nozzle 249a from the lower portion of the reaction tube 203 to the upper portion thereof. The gas supply holes 250a have the same area and pitch.

A first process gas supply system is constituted by the gas supply pipe 232a, the ventilation line 232d, the valves 243a and 243d, the MFC 241a, the vaporizer 271a, the mist filter 300, the gas filter 272a and the nozzle 249a. A first inert gas supply system is constituted by the inert gas supply pipe 232c, the MFC 241c and the valve 243c.

An ozonizer 500 capable of generating ozone (O₃) gas, a valve 243f, a mass flow controller (MFC) 241b which is a flow rate controller (flow rate control device) and a valve 243b which is an opening/closing valve are provided at the gas supply pipe 232b in order from the upstream side toward the downstream side of the gas supply pipe 232b. An oxygen gas source (not shown) for supplying oxygen (O₂) gas is connected to the upstream side of the gas supply pipe 232b.

O₂ gas supplied to the ozonizer 500 is converted into O₃ gas by the ozonizer 500 and O₃ gas is then supplied into the process chamber 201. A ventilation line 232g connected to the exhaust pipe 231, which will be described later, is connected to the gas supply pipe 232b between the ozonizer 500 and the valve 243f. A valve 243g, which is an opening/closing valve, is provided at the ventilation line 232g. When O₃ gas is not supplied to the process chamber 201, the O₃ gas is supplied to the ventilation line 232g via the valve 243g. By closing the valve 243f and opening the valve 243g, the supply of O₃ gas into the process chamber 201 may be stopped even when O₃ gas is continuously generated by the ozonizer 500.

A certain amount of time is required to stably generate O₃ gas. The operation of switching between the valve 243f and the valve 243g reduces the time required for switching between the supply of O₃ gas into the process chamber 201 and the suspending of the supply of O₃ gas. The inert gas supply pipe 232e is connected to the downstream side of the valve 243b at the gas supply pipe 232b. A mass flow controller (MFC) 241e which is a flow rate controller (flow rate control device) and a valve 243e which is an opening/closing valve are provided at the inert gas supply pipe 232e in order from the upstream side toward the downstream side of the inert gas supply pipe 232e.

The nozzle 249b is connected to the front end portion of the gas supply pipe 232b. The nozzle 249b is provided in an annular space between the inner wall surface of the reaction tube 203 and the wafers 200, and extends from bottom to top of the inner wall of the reaction tube 203 along the stacking direction of the wafers 200. For example, the nozzle 249b includes an L-shaped long nozzle.

A plurality of gas supply holes 250b for supplying gases is provided at the side surface of the nozzle 249b. The gas supply holes 250b are open to face to the center of the reaction tube 203. The plurality of gas supply holes 250b is provided at the nozzle 249b from the lower portion of the reaction tube 203 to the upper portion thereof. The plurality of gas supply holes 250b has the same aperture area and aperture pitch.

A second process gas supply system is constituted by the gas supply pipe 232b, the ventilation line 232g, the ozonizer 500, the valves 243f, 243g and 243b, the MFC 241b and the nozzle 249b. A second inert gas supply system is constituted by the inert gas supply pipe 232e, the MFC 241e and the valve 243e.

A zirconium (Zr) source gas, that is, a gas containing zirconium (zirconium-containing gas) which is a first source gas, is supplied into the process chamber 201 via the vaporizer 271a, the mist filter 300, the gas filter 272a, the MFC 241a and the valve 243a, which are provided at the gas supply pipe 232a, and the nozzle 249a. For example, the zirconium-containing gas includes tetrakis (ethylmethylamino) zirconium (TEMAZ) gas. Tetrakis (ethylmethylamino) zirconium (TEMAZ) is liquid under room temperature and atmospheric pressure.

A gas containing oxygen (O) (oxygen-containing gas) such as O₂ gas is supplied to the gas supply pipe 232b, and is then converted into O₃ gas by the ozonizer 500. O₃ gas is then supplied as an oxidizing gas (oxidizing agent) into the process chamber 201 via the valve 243f, the MFC 241b and the valve 243b. O₂ gas, which is also an oxidizing gas, may be directly supplied into the process chamber 201 without being converted into O₃ gas by the ozonizer 500.

The inert gas such as nitrogen (N₂) gas is supplied into the process chamber 201 via the MFCs 241c and 241e and the valves 243c and 243e provided at the inert gas supply pipes 232c and 232e, the downstream sides of the gas supply pipes 232a and 232b and the nozzles 249a and 249b, respectively.

The exhaust pipe 231 for exhausting the inner atmosphere of the process chamber 201 is provided at the lower sidewall of the reaction tube 203. A vacuum pump (vacuum exhaust device) 246 is connected to the exhaust pipe 231 via a pressure sensor 245 and an APC (Automatic Pressure Controller) valve 244. The pressure sensor 245 serves as a pressure detector (pressure detection mechanism) which detects the inner pressure of the process chamber 201, and the APC valve 244 serves as a pressure controller (pressure adjusting mechanism).

With the vacuum pump 246 in operation, the APC valve 244 may be opened/closed to vacuum-exhaust the process chamber 201 or stop the vacuum exhaust. With the vacuum pump 246 in operation, the opening degree of the APC valve 244 may be adjusted in order to control the inner pressure of the process chamber 201. The exhaust pipe 231, the APC valve 244, the vacuum pump 246 and the pressure sensor 245 constitutes an exhaust system.

A temperature sensor 263, which is a temperature detector, is provided in the reaction tube 203. The energization state of the heater 207 is controlled based on the temperature detected by the temperature sensor 263 such that the inner temperature of the process chamber 201 has a desired temperature distribution. The temperature sensor 263 is L-shaped similar to the nozzles 249a and 249b. The temperature sensor 263 is provided along the inner wall of the reaction tube 203.

As shown in FIG. 3, a controller (control device or control means) 121 is embodied by a computer including a CPU (Central Processing Unit) 121a, a RAM (Random Access Memory) 121b, a memory device 121c and an I/O port 121d. The RAM 121b, the memory device 121c and the I/O port 121d may exchange data with the CPU 121a through an internal bus. For example, an input/output device 122 such as a touch panel is connected to the controller 121. An external memory device (recording medium) 123 may be connected to the controller 121. The external memory device 123 stores a program, which will be described later.

The memory device 121c is embodied by components such as a flash memory and HDD (Hard Disk Drive). A control program for controlling the operation of the substrate processing apparatus or a process recipe containing information on the sequence and conditions of a substrate processing is readably stored in the memory device 121c. The external memory device 123 may also store the control program or the process recipe. By connecting the external memory device 123 to the controller 121, the control program or the process recipe may be transferred to and readably stored in the memory device 121c.

The process recipe, which functions as a program, is created by combining steps of the substrate processing such that the controller 121 may execute the steps to acquire a predetermine result. Hereafter, the process recipe and the control program are collectively referred to as “program.”

Herein, “program” may indicate only the process recipe, only the control program, or both. The RAM 121b is a work area where a program or data read by the CPU 121a is temporarily stored.

The I/O port 121d is connected to the components such as the mass flow controllers (MFCs) 241a, 241b, 241c and 241e, the valves 243a, 243b, 243c, 243d, 243e, 243f and 243g, the vaporizer 271a, the mist filter 300, the ozonizer 500, the pressure sensor 245, the APC valve 244, the vacuum pump 246, the heaters 150 and 207, the temperature sensor 263, the rotating mechanism 267 and the boat elevator 115.

The CPU 121a is configured to read a control program from the memory device 121c and execute the control program. Furthermore, the CPU 121a is configured to read a process recipe from the memory device 121c according to an operation command from the input/output device 122

According to the contents of the process recipe, the CPU 121a controls various operations such as flow rate adjusting operations of the mass flow controllers (MFCs) 241a, 241b, 241c and 241e for various gases, opening/closing operations of the valves 243a, 243b, 243c, 243d, 243e, 243f and 243g, an opening/closing operation of the APC valve 244, a pressure adjusting operation by the APC valve 244 based on the pressure detected by the pressure sensor 245, a temperature adjusting operation of the heater 150, a temperature adjusting operation of the heater 207 based on the temperature measured by the temperature sensor 263, operations of the vaporizer 271a, the mist filter 300 and the ozonizer 500, a start and stop of the vacuum pump 246, a rotation speed adjusting operation of the rotating mechanism 267 and an elevating operation of the boat 217 by the boat elevator 115.

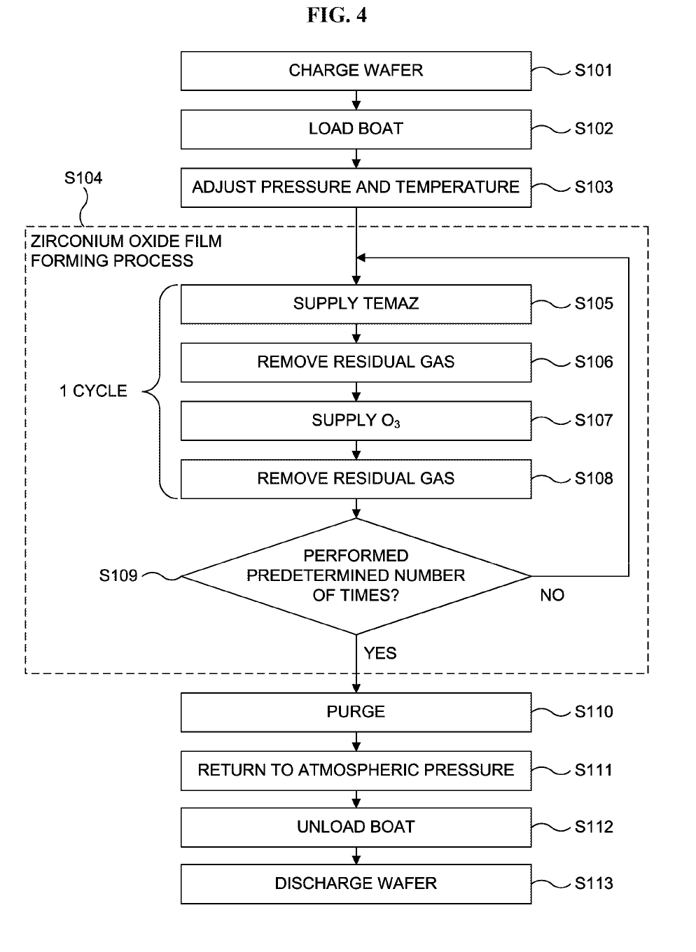

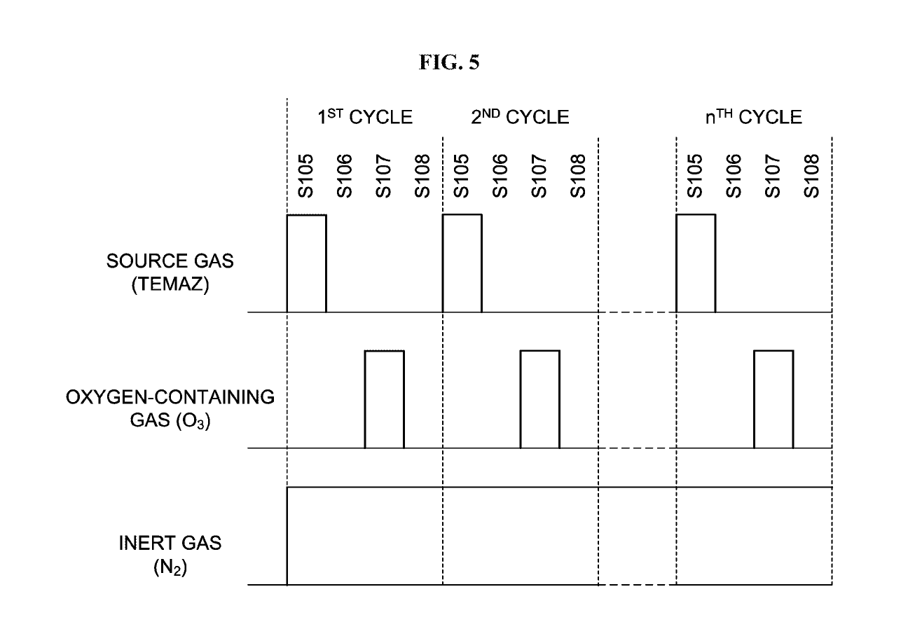

Next, an exemplary film-forming sequence of forming an insulating film on a substrate, which is a substrate processing for manufacturing a semiconductor device, using the above-described substrate processing apparatus will be described with reference to FIGS. 4 and 5. Herein, the components of the substrate processing apparatus are controlled by the controller 121.

For example, multiple types of gases including a plurality of elements constituting a film to be formed are simultaneously supplied to form the film. Alternatively, multiple types of gases including a plurality of elements constituting the film to be formed may be supplied in turn.

Wafers 200 are charged into the boat 217 (wafer charging: step S101 of FIG. 4). The boat 217 charged with the wafers 200 is lifted by the boat elevator 115 and loaded into the process chamber 201 (boat loading: step S102 of FIG. 4). With the boat 217 loaded, the seal cap 219 seals the lower end of the reaction tube 203 via the O-ring 220.

The vacuum pump 246 vacuum-exhausts the process chamber 201 such that the inner pressure of the process chamber 201 is adjusted to a desired level (vacuum level). Simultaneously, the inner pressure of the process chamber 201 is measured by the pressure sensor 245, and the APC valve 244 is feedback-controlled based on the measured pressure (pressure adjusting: step S103 of FIG. 4).

The heater 207 heats the process chamber 201 until the inner temperature of the process chamber 201 reaches a desired temperature. The energization state of the heater 207 is feedback-controlled based on the temperature detected by the temperature sensor 263 such that the inner temperature of the process chamber 201 has a desired temperature distribution (temperature adjusting: step S103 of FIG. 4). The rotating mechanism 267 starts to rotate the boat 217 and the wafers 200.

<Insulating Film Forming Process>

Next, an insulating film forming process (zirconium oxide film forming process: step S104 OF FIG. 4) for forming a ZrO film, which is an insulating film, is performed by supplying TEMAZ gas and O₃ gas to the process chamber 201. Steps S105 through S108 are performed sequentially in the insulating film forming process.

<Step S105>

As shown in FIGS. 4 and 5, TEMAZ gas is supplied to the wafers 200 in the process chamber 201 in the step (first step) S105. By opening the valve 243a at the gas supply pipe 232a and closing the valve 243d at the ventilation line 232d, TEMAZ gas is supplied to the gas supply pipe 232a via the vaporizer 271a, the mist filter 300 and the gas filter 272a. After the flow rate of TEMAZ gas is adjusted by the MFC 241a, the TEMAZ gas is supplied into the process chamber 201 through the gas supply holes 250a of the nozzle 249a and exhausted via the exhaust pipe 231. Simultaneously, the valve 243c is opened to supply an inert gas such as N₂ gas into the inert gas supply pipe 232c. After the flow rate of N₂ gas is adjusted by the MFC 241c, the N₂ gas is supplied along with the TEMAZ gas into the process chamber 201 and exhausted via the exhaust pipe 231. A zirconium-containing layer is formed on the wafer 200 by the reaction between TEMAZ gas supplied into the process chamber 201 and the wafer 200.

At this point, the APC valve 244 is controlled such that the inner pressure of the process chamber 201 ranges, for example, from 50 Pa to 400 Pa. The flow rate of the TEMAZ gas adjusted by the MFC 241a ranges, for example, from 0.1 g/min to 0.5 g/min. The duration of the exposure of the wafer 200 to TEMAZ gas, i.e. the time duration of supply of the TEMAZ gas onto the wafer 200, ranges, for example, from 30 second to 240 seconds. The heater 207 is controlled such that the temperature of the wafers 200 ranges, for example, from 150° C. to 250° C.

<Step S106>

As shown in FIGS. 4 and 5, after the zirconium-containing layer is formed in the step S105, the valve 243a is closed and the valve 243d is opened to stop the supply of the TEMAZ gas into the process chamber 201 and to supply the TEMAZ gas to the ventilation line 232d in the step (second step) S106. With the APC valve 244 of the exhaust pipe 231 open, the vacuum pump 246 vacuum-exhausts the process chamber 201 to remove residual TEMAZ gas which did not react or contributed to the formation of the zirconium-containing layer from the process chamber 201. By maintaining the valves 243c open, the N₂ gas is continuously supplied into the process chamber 201. The N₂ gas is continuously supplied into the process chamber 201 to improve an efficiency of removing the residual TEMAZ gas which did not react or contributed to the formation of the zirconium-containing layer from the process chamber 201. While the N₂ gas is exemplified as the inert gas, rare gases such as argon (Ar) gas, helium (He) gas, neon (Ne) gas and xenon (Xe) gas may be used as the inert gas instead of the N₂ gas.

<Step S107>

As shown in FIGS. 4 and 5, after the residual TEMAZ gas is removed from the process chamber 201 in the step S106, O₂ gas is supplied to the gas supply pipe 232b in the step (third step) S107. The O₂ gas supplied to the gas supply pipe 232b is converted to O₃ gas by the ozonizer 500. By opening the valves 243f and 243b at the gas supply pipe 232b and closing the valve 243g at the ventilation line 232g, O₃ gas flows to the MFC 241b and the flow rate of O₃ gas is adjusted by the MFC 241b. The O₃ gas with the flow rate thereof adjusted by the MFC 241b is supplied into the process chamber 201 through the plurality of gas supply holes 250b of the nozzle 249b and then exhausted through the exhaust pipe 231. Simultaneously, the valve 243e is opened to supply an inert gas such as N₂ gas into the inert gas supply pipe 232e. The N₂ gas is supplied along with the O₃ gas into the process chamber 201 and then exhausted through the exhaust pipe 231. A zirconium oxide (ZrO) layer is formed by the reaction between the zirconium-containing layer formed on the wafer 200 and the O₃ gas supplied into the process chamber 201.

When the O₃ gas is supplied to the gas supply pipe 232b, the APC valve 244 is controlled such that the inner pressure of the process chamber 201 ranges, for example, from 50 Pa to 400 Pa. The flow rate of the O₃ gas adjusted by the MFC 241b ranges from, for example, 10 slm to 20 slm. The duration of the exposure of the wafer 200 to O₃ gas, i.e. the time duration of supply of the O₃ gas onto the wafer 200, ranges, for example, from 60 second to 300 seconds. Similar to the step S105, the heater 207 is controlled such that the temperature of the wafers 200 ranges, for example, from 150° C. to 250° C.

<Step S108>

As shown in FIGS. 4 and 5, the valve 243b at the gas supply pipe 232b is closed to stop the supply of the O₃ gas into the process chamber 201 and the valve 243g at the ventilation line 232g is opened to supply the O₃ gas to the ventilation line 232g in the step (fourth step) S108. With the APC valve 244 at the exhaust pipe 231 open, the vacuum pump 246 vacuum-exhausts the process chamber 201 to remove residual O₃ gas which did not react or contributed to the formation of the zirconium oxide layer from the process chamber 201. By maintaining the valve 243e open, the N₂ gas is continuously supplied into the process chamber 201. The N₂ gas is continuously supplied into the process chamber 201 to improve an efficiency of removing the residual O₃ gas which did not react or contributed to the formation of the zirconium oxide layer from the process chamber 201. While the O₃ gas is exemplified as the oxygen-containing gas, gas such as O₂ gas may be used as the oxygen-containing gas instead of the O₃ gas.

A cycle including the first step S105 through the fourth step S108 is performed at least once in the step S109 to form the zirconium oxide film having a desired thickness on the wafers 200. It is preferable that the cycle is performed a plurality of times until the zirconium oxide film having the desired thickness is formed on the wafers 200.

After the zirconium oxide film is formed on the wafers 200, the valve 243a at the gas supply pipe 232a and the valve 243b at the gas supply pipe 232b are closed and the valve 243c at the inert gas supply pipe 232c and the valve 243e of the inert gas supply pipe 232e are opened to supply the N₂ gas into the process chamber 201. The N₂ gas serves as a purge gas. The process chamber 201 is thereby purged such that the gas remaining in the process chamber 201 is removed from the process chamber 201 (purging: step S110). Thereafter, the inner atmosphere of the process chamber 201 is replaced with the inert gas, and the inner pressure of the process chamber 201 is returned to atmospheric pressure (returning to atmospheric pressure: step S111).

Thereafter, the seal cap 219 is lowered by the boat elevator 115 and the lower end of the reaction tube 203 is opened. The boat 217 with the processed wafers 200 charged therein is unloaded from the reaction tube 203 through the lower end of the reaction tube 203 (boat unloading: step S112). After the boat 217 is unloaded, the processed wafers 200 are then discharged from the boat 217 (wafer discharging: step S113).

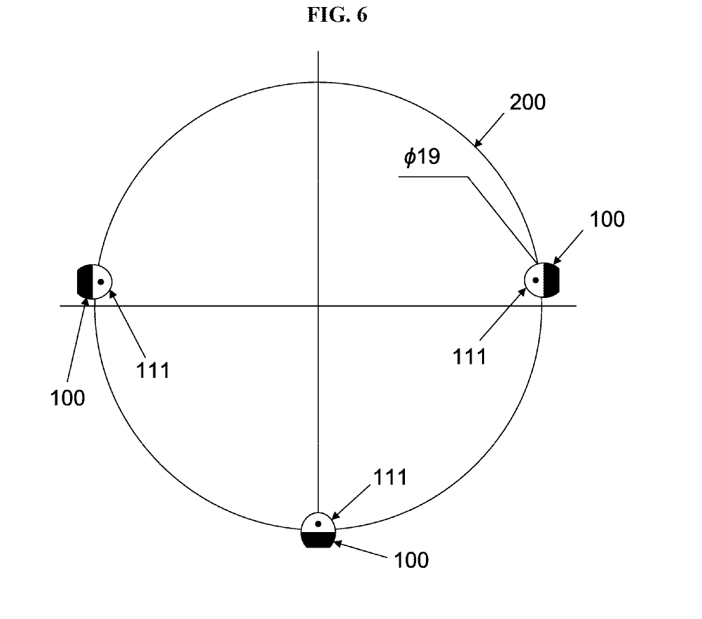

During the substrate processing described above, the edge of the wafer 200 is inserted into and supported by grooves 111 engraved in support columns 100 of the conventional boat shown in FIG. 6. However, since the support columns 100, which are in the close proximity of the wafer 200, consume gases, the uniformity of the film formed on the wafer is degraded.

In particular, the effect of the support columns 100 on the uniformity of the thickness of the film cannot be ignored as the film becomes thinner in recent substrate processing. Since the effect on the uniformity of the thickness of the film formed on the surface of the wafer 200 increases as the surface area of the support columns 100 becomes larger, it is preferable that the diameter of each of the support columns 100 and the surface area of each of the support columns 100 are small.

The inventors of the present application have discovered that the effect on the uniformity of the thickness of the film due to a gas consumption by the support columns 100 can be reduced by changing the structure of the boat.

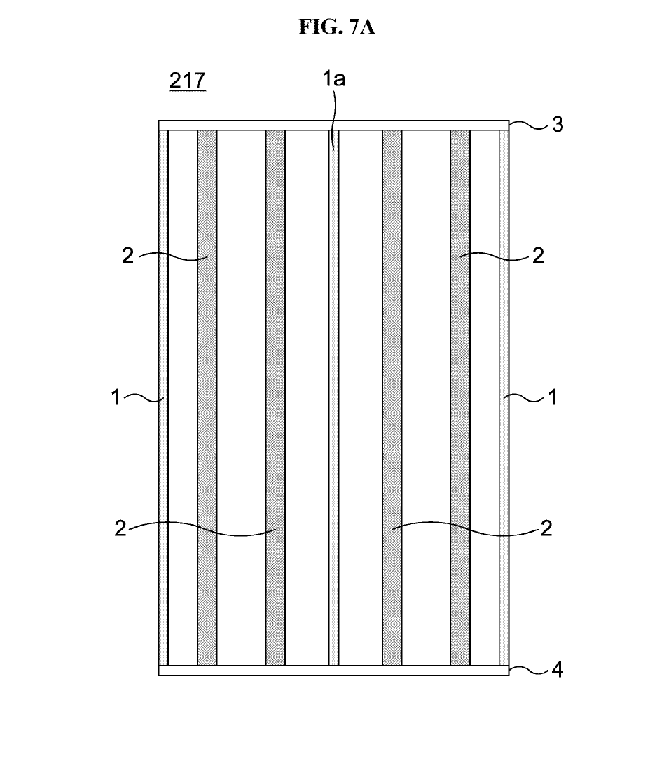

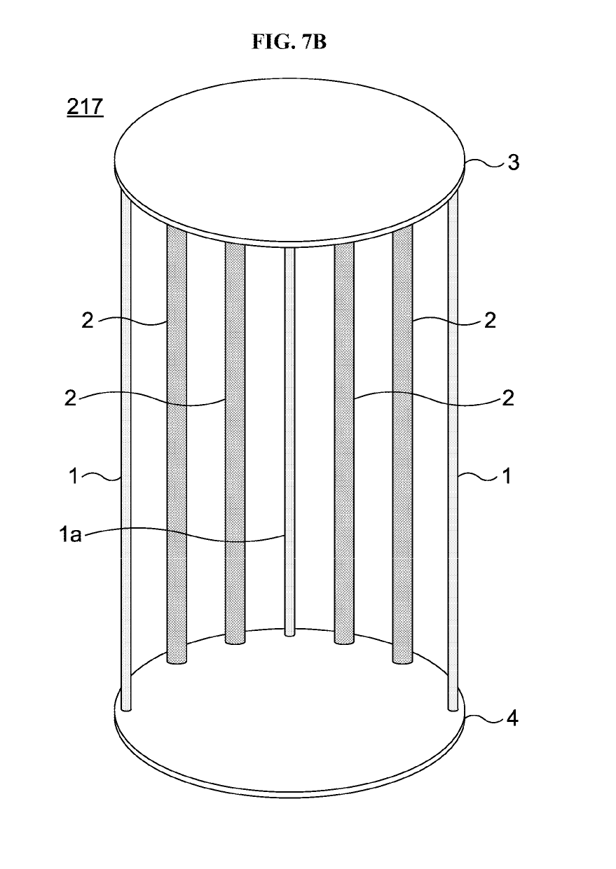

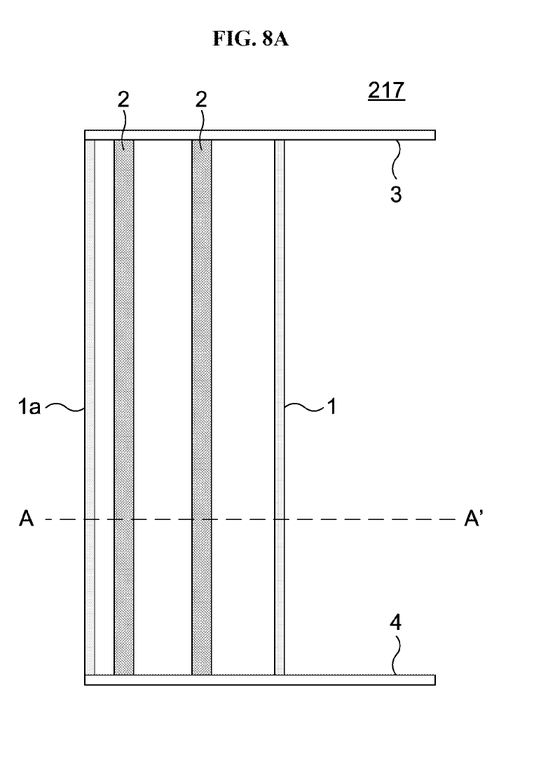

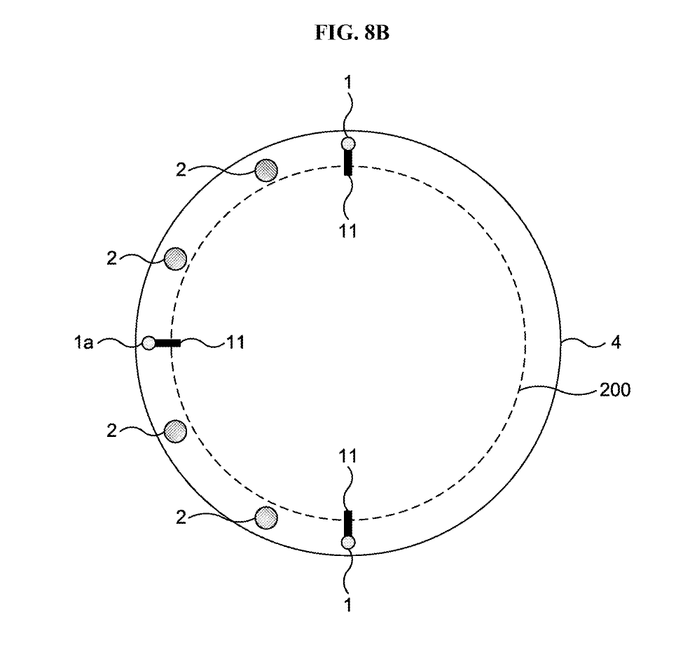

FIGS. 7A, 7B, 8A and 8B schematically illustrate the boat 217 according to the embodiment. For simplification, pins (substrate support members) 11 are only shown in FIG. 8B and are not shown in FIGS. 7A, 7B and 8A. In FIG. 8B, the wafer (substrate) 200 placed on the pins 11 is denoted by dashed line.

As shown in FIGS. 7A, 7B, 8A and 8B, the boat 217 according to the embodiment includes: an upper plate 3; a lower plate 4; at least three main support columns 1 provided along the peripheries of the upper plate 3 and the lower plate 4 and configured to support the wafer 200; and four (preferably at least three) auxiliary support columns 2 provided along the peripheries of the upper plate 3 and the lower plate 4. Each of the auxiliary support columns 2 has diameter greater than those of the main support columns 1, and the auxiliary support columns 2 do not support the wafer 200. That is, the auxiliary support columns 2 are not in contact with the wafer 200. The pins 11 whereon the wafer 200 is placed are provided on the surface of the main support columns 1.

The wafer 200 is placed on the pins 11 in a manner that the edge (side surface) of the wafer 200 is spaced apart from the main support columns 1. According to the embodiment, the main support columns 1 are provided along the peripheries of the upper plate 3 and the lower plate 4, respectively. By making the diameter of each of the main support columns 1 smaller, the distance between the edge of the wafer 200 and the surface of each of the main support columns 1 is increased.

It is preferable that the edge of the wafer 200 is spaced apart from the main support columns 1 and the wafer 200 is not in contact with the auxiliary support columns 2 when the wafer 200 is placed on the pin 11. It is also preferable that the main support columns 1 and the support columns 2 are provided at the locations where they don't affect a result of the substrate processing.

It is preferable that the diameter of each of the auxiliary support columns 2 is larger than that of each of the main support columns 1 such that the boat 217 including the upper plate 3 and the lower plate 4 coupled by the auxiliary support columns 2 can withstand a plurality of wafers 200 charged therein. In order to minimize the effect on the substrate processing, the auxiliary support columns 2 are not provided with the pins 11 supporting the wafer 200. The number of the auxiliary support columns 2 is greater than the number of the main support columns 1 to maintain the strength of the boat 217 accommodating the plurality of wafers 200.

As described above, it is preferable that the diameter of each of the auxiliary support columns 2 is larger than that of each the main support columns 1 and smaller than a length of each of the pins 11. However, the diameter of each of the auxiliary support columns 2 may be substantially the same as the length of each of the pins 11 as long as the auxiliary support columns 2 are not in contact with the wafer 200. For example, the diameter of each of the main support columns 1 ranges from 3 mm to 10 mm, the diameter of each of the auxiliary support columns 2 ranges from 8 mm to 15 mm, and the length of each of the pins 11 ranges from 20 mm to 30 mm.

Herein, the above-described numerical ranges include the lower limits and the upper limits of the numerical ranges, respectively. For example, “from 20 mm to 30 mm” means “equal to or greater than 20 mm and equal to or smaller than 30 mm.”

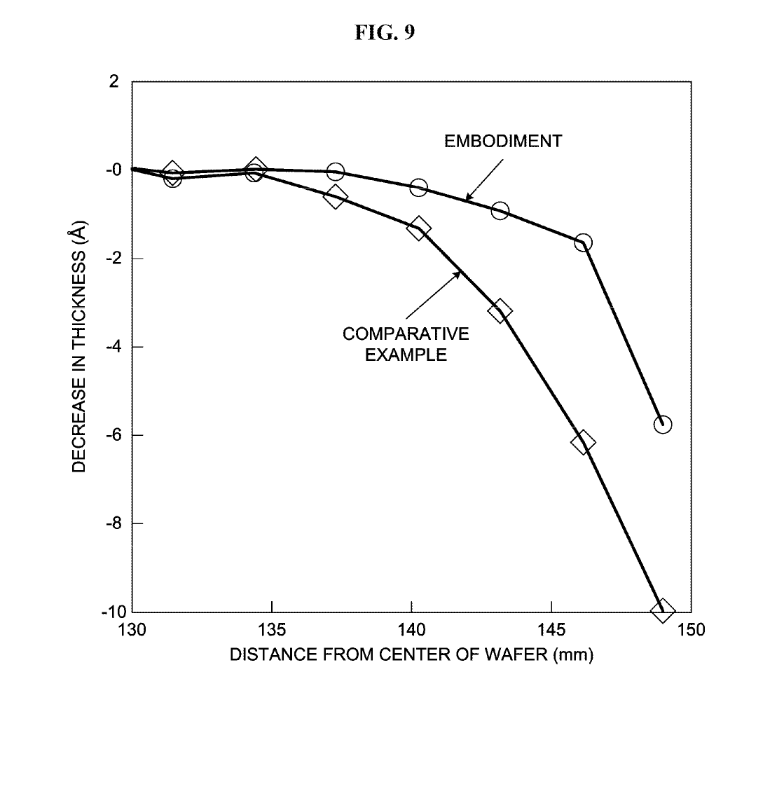

FIG. 9 is a graph showing a decrease in the thickness of the film on the wafer 200 according to the first comparative example shown in FIG. 9 and a decrease in the thickness of the film on the wafer 200 according to the embodiment. In FIG. 9, the horizontal axis represents the distance (unit: mm) from the center of the wafer 200, and the vertical axis represents the decrease in thickness (unit: A) with respect to the thickness of the film at the center of the wafer 200. As shown in FIG. 9, according to the first comparative example, the thickness of the film is decreased about 10 Å from the center of the wafer 200 to the edge of the wafer 200, while the thickness of the film is decreased about 5 Å from the center of the wafer 200 to the edge of the wafer 200 according to an embodiment.

Referring to the graph shown in FIG. 9, the thinning of the film due to the effect of the main support columns 1 starts from a location about 12 mm from the edge of the wafer 200. Assuming that the distance between the surface of each of the main support columns 1 and the edge of the wafer 200 is about 5 mm, the effect of the main support columns 1 on the thickness of the film reaches a location about 17 mm from the center of the wafer 200. Assuming that the minimum length of each of the pins 11 necessary for supporting the wafer 200 is 3 mm, it is preferable that the length of each of the pins 11 is at least 20 mm (=17 mm+3 mm). As the increase in the contact area between the pins 11 and the wafer 200 causes more temperature drop in the wafer 200 due to heat conduction, it is preferable that the maximum length of the pins 11 is 30 mm.

Preferably, the diameter of each of the main support columns 1 ranges from 3 mm, which is the minimum diameter for securing the strength required to support the wafer 200, to 10 mm, which is the maximum diameter limited by the pins 11 and the reaction tube 203. Preferably, the diameter of each of the auxiliary support columns 2 ranges from 8 mm which is the minimum diameter for securing the strength of the boat 217, to 15 mm, which is the maximum diameter that secures maximum of 2% decrease in the thickness of the film with respect to the average thickness of the film.

As shown in FIGS. 7A and 7B, two auxiliary support columns 2 are provided at the same interval between the two main support columns 1. As shown in FIGS. 7A and 7B, the boat 217 includes at least three main support columns 1, one of which is a reference column 1a. The reference column 1a is provided in-line with the charging/discharging direction of the wafer 200, and two main support columns 1 other than the reference column 1a are symmetrically arranged about the reference column 1a at both sides of the reference column 1a.

At least three auxiliary support columns 2 are also symmetrically arranged about the reference column 1a at both sides of the reference column 1a along the peripheries of the upper plate 3 and the lower plate 4. That is, the reference column 1a is at the vertex of a semicircle along which the auxiliary support columns 2 and the main support columns 1 are arranged. As shown in FIGS. 7A and 7B, two pairs of the auxiliary support columns 2 are provided between adjacent two main support columns 1. Since the diameter of each of the auxiliary support columns 2 is larger than the diameter of each of the main support columns 1 to provide sufficient strength for the boat 217, the number of the auxiliary support columns 2 may be less than the number of the main support columns 1.

For example, the diameter of each of the support columns 100 of the conventional boat of the first comparative example shown in FIG. 6 is 19 mm, and the diameter of each of the main supports columns 1 and the diameter of each of the auxiliary support columns 2 of the boat 217 shown in FIG. 7 is 10 mm and is 15 mm, respectively. According to the embodiment, the diameter of each of the main support columns 1 is smaller than the diameter of each of the auxiliary support columns 2 such that the effect of the main support columns 1 on the substrate processing is minimized as well as that the main support columns 1 are spaced apart from the edge of the wafer 200. By reducing the diameter of each of the main support columns 1, the thermal capacity of each of the main support columns 1 and the effect on the substrate processing due to the heat conduction from the wafer 200 to the pins 11 are minimized.

Since the diameter (i.e. cross-section) of each of the main support column 1 is small, it is necessary to increase the diameter of each of the auxiliary support columns 2 to ensure the strength of the boat 217. That is, when the strength of the boat 217 is ensured by increasing the diameter of each of the auxiliary support columns 2, the diameters of each of the main support columns 1 having the pins 11 thereon can be reduced. However, the diameter of each of the main support columns 1 should be sufficiently large to secure the strength to support the wafer 200. The length of each of the pins 11 is determined in a manner that the auxiliary support columns 2 do not come in contact with the wafer 200.

While the diameter of each of the support columns 100 of the conventional boat shown in FIG. 6 is 19 mm, the diameter of each of the main support columns 1 of the boat 217 shown in FIG. 7 is 10 nm. That is, the main support columns 1 are thinner than the support columns 100. Thus, the distance between the edge of the wafer 200 and the surface of each of the main support columns 1 and is about twice the distance between the edge of the wafer 200 and the surface of the support columns 100. Since the surface areas of the main support columns 1 supporting the wafer 200 become smaller as the diameter of each of the main support columns 1 becomes smaller, the flow of the film-forming gas is not interfered with flow. As a result, the consumption of film-forming gas by the main support columns 1 is suppressed.

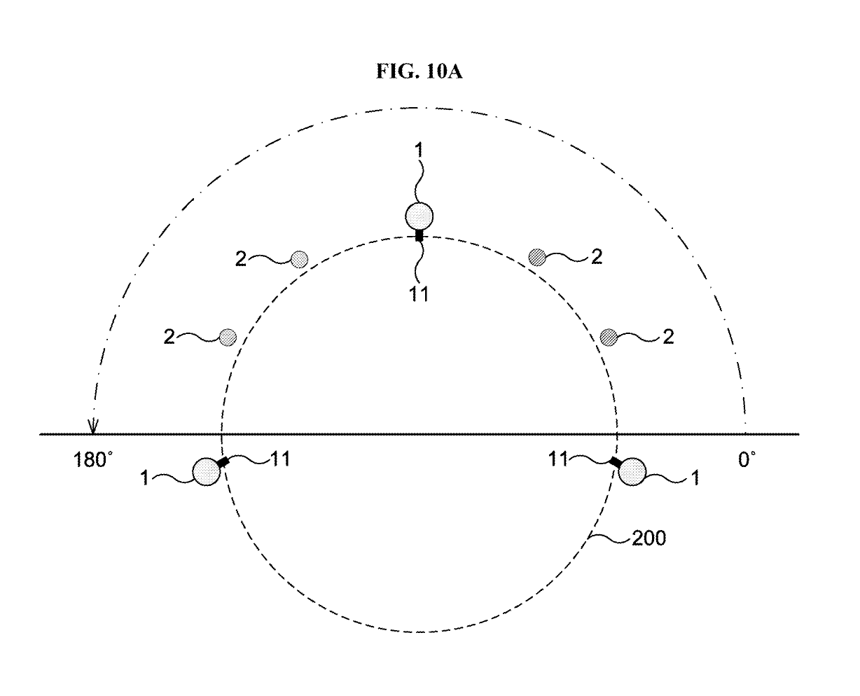

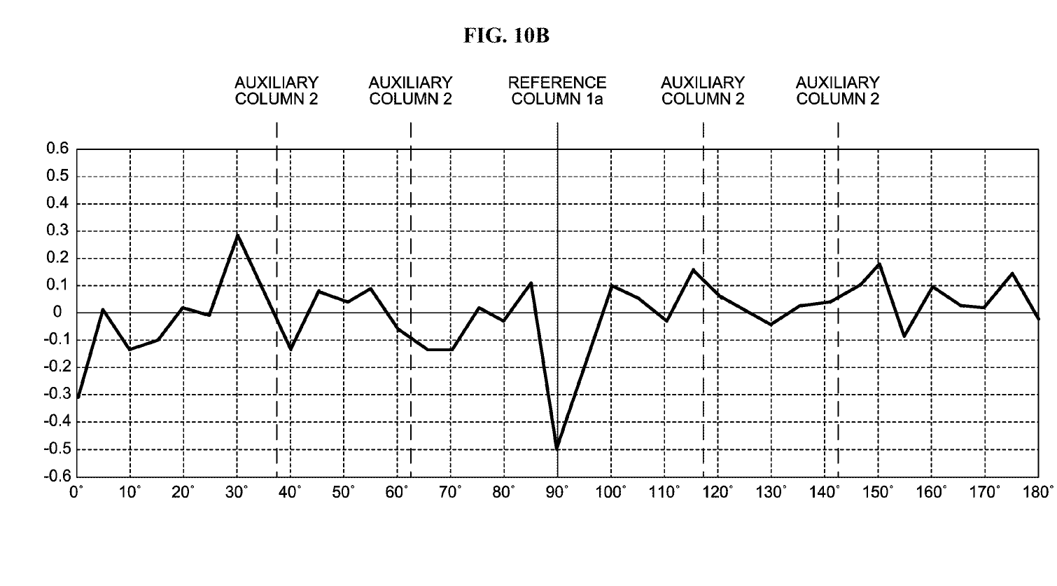

FIG. 10A illustrates a second comparative example different from the first comparative example shown in FIG. 6. Referring to FIG. 10A, the main support columns 1 and the auxiliary support columns 2 according to the second comparative example are provided at locations substantially the same locations as the main support columns 1 and the auxiliary support columns 2 according to the embodiment shown in FIG. 8B. According to the second comparative example, the diameter of each of the main support columns 1 is greater than the diameter of each of the auxiliary support columns 2. FIG. 10B is a graph illustrating the effects of the main support columns 1 and the auxiliary support columns 2 of FIG. 10A on the thickness of the film at a location 10 mm from the edge of the wafer 200 in the circumferential direction of the wafer 200 (denoted by a dash-dot line in FIG. 10A) to the main support columns 1 and the auxiliary support columns 2).

According to the second comparative example shown in FIG. 10A, the diameter of each of the main support columns 1 is 10 mm, the diameter of each of the auxiliary support columns 2 is 8 mm, the distance between the edge of the wafer 200 and the surface of the main support columns 1 is 4 mm, and the distance between the edge of the wafer 200 and the surface of the auxiliary support columns 2 is 2 mm. Similar to the embodiment shown in FIG. 8B, a pair of the auxiliary support columns 2 are provided at each side of the reference column 1a symmetric about the reference column 1a at both sides of.

The horizontal axis of the graph shown in FIG. 10B represents the angle in the circumferential direction of the wafer 200 denoted by a dash-dot line in FIG. 10A, and the vertical axis represents the difference between the thickness of the film and the average thickness of the film at the location 10 mm from the edge of the wafer 200. As shown in FIG. 10B, while the overall difference in thickness is within 0.3 Å, the difference in thickness near the main support columns 1 is greater (e.g., 0.5A in FIG. 10B).

Referring to FIG. 10B, the difference in thickness is far greater near the pins 11 which are in contact with the wafer 200. The auxiliary support columns 2 have little effect on the thickness of the film despite that the distance of 2 mm between the edge of the wafer 200 and the surface of the auxiliary support columns 2 is shorter than the distance of 4 mm between the edge of the wafer 200 and the surface of the main support columns 1.

Since the auxiliary support columns 2 are not in contact with the wafer 200, the auxiliary support columns 2 have little effect on the thickness of the film. That is, as long as the auxiliary support columns 2 are not in contact with the wafer 200 and the auxiliary support columns 2 are at least 2 mm spaced apart from the edge of the wafer 200, the auxiliary support columns 2 have little effect on the thickness of the film despite the large diameters thereof.

If the diameter of each of the main support columns 1 (10 mm) is greater than the diameter of each of the auxiliary support columns 2 (8 mm), that is, the cross-section of each of the main support columns 1 is greater than the cross-section of each of the auxiliary support columns 2, the effect of the main support columns 1 on the thickness of the film is significant. More process gas is adsorbed to and consumed by the main support columns 1, thereby lowering the concentration of the process gas around the main support columns 1. As a result, the uniformity of the film on the surface of the wafer 200 is affected.

<Effects of the Columns>

It is preferable that the main support columns 1 and the auxiliary support columns 2 are both thin and have small surface area. However, since the auxiliary support columns 2 must be close to the wafer 200 to assure the strength of the boat 217, it is preferable that the distance L between the edge of the wafer 200 and the main support columns 1 and the distance S between the edge of the wafer 200 and the auxiliary support columns 2 satisfy L>S. That is, it is preferable that the distance S between the edge of the wafer 200 and the auxiliary support columns 2 is shorter than the distance L between the edge of the wafer 200 and the main support columns 1 and

While it is difficult to completely eliminate the effects of the main support columns 1 and the auxiliary support columns 2, the decrease in the thickness of the film due to the main support columns 1 and the auxiliary support columns 2 may be suppressed by distributing the effects of the main support columns 1 and the auxiliary support columns 2 according to the embodiment. In particular, when the ratio of the surface area of each of the auxiliary support columns 2 to the surface area of each of the main support columns 1 ranges from 1.3 to 5.0, the uniformity of the film of the surface of the wafer 200 is improved.

According to the embodiment, the strength of the boat 217 can be maintained while preventing the decrease in the thickness of the film by increasing the thickness of each of the auxiliary support columns 2 having no pins 11, which have less effect on the thickness of the film than the main support columns 1. It is preferable that the minimum ratio of the surface area of each of the main support columns 1 to the surface area of each of the auxiliary support columns 2 is 1.3 (for example, the diameter of each of the main support columns is 10 mm and the diameter of each of the auxiliary support columns 2 is 13 mm). it is also preferable that the maximum ratio of the surface area of each of the main support columns 1 to the surface area of each of the auxiliary support columns 2 is 5.0 (for example, the diameter of each of the main support columns 1 is 3 mm and the diameter of each of the auxiliary support columns 2 is 15 mm).

According to the embodiment, the diameters of the auxiliary support columns 2 are the same as one another. However, the diameters of the auxiliary support columns 2 may be different from one another as long has the auxiliary support columns 2 provides sufficient strength for the boat 217.

According to the embodiment, the diameter of each of the auxiliary support columns 2 is larger than the diameter of each of the main support columns 1. However, the diameter of each of the auxiliary support columns 2 may be smaller than the diameter of each of the main support columns 1 as long as the substrate retainer does not affect the uniformity of the thickness of the film and the degradation of the uniformity of the thickness of the film is suppressed.

According to the embodiment, three main support columns 1 and four auxiliary support columns 2 which are provided between the main support columns 1, are provided along the circumferential direction of the wafer 200 at an even interval. However, the above-described technique is not limited thereto. For example, the numbers and locations of the main support columns 1 and the auxiliary support columns 2 may be changed. The cross-sections of the main support columns 1 and the auxiliary support columns 2 may be circular, semi-circular, elliptical or polygonal.

In order to improve the strength of the boat 217 against transverse stresses, a semicircular joint may be provided at the middle portion of the main support columns 1. The semicircular connector couples the main support columns 1 to one another along the circumferential direction of the substrate.

According to the embodiment, one or more advantageous effects described below are provided.

(a) Since the substrate is supported by the substrate retainer without any contact between the edge of the substrate and the auxiliary support columns, the uniformity of the thickness of the film is not affected and the degradation of the uniformity of the thickness of the film is suppressed despite the increase in the total number of supports due to the increase in the number of auxiliary support columns.

(b) The pins (substrate support members) supporting the substrate are provided on the surface of each of the main support columns of the substrate retainer. The auxiliary support columns are provided to reinforce the strength of the substrate retainer, and the pins are not provided on the auxiliary support columns. When the main support columns and the auxiliary support columns are provided in a manner that the distance between the edge of the substrate and each of the auxiliary support columns is equal to or longer than a predetermined distance (e.g. 2 mm), the uniformity of the thickness of the film is hardly affected by the substrate retainer. Therefore, the degradation of the uniformity of the thickness of the film can be suppressed.

(c) By reducing the diameter of each of the main support column provided with substrate support members that have a significant effect on the substrate processing using the substrate retainer, the effect of the substrate retainer on the substrate processing may be minimized. The strength of the substrate retainer is maintained by making the diameter of each of the auxiliary support columns, which have little effect on the substrate processing, larger than the diameter of each of the main support columns with no substrate support members.

While the technique is described in detail by way of the embodiment, the above-described technique is not limited thereto. The above-described technique may be modified in various ways without departing from the gist thereof.

The process recipe stored in the substrate processing apparatus for the above-described substrate processing according to the embodiment may be changed to a new process recipe according to the embodiment. When changing the process recipe to the new process recipe, the new process recipe may be installed in the substrate processing apparatus via the telecommunication line or the recording medium in which the new process recipe is stored. The process recipe stored in the substrate processing apparatus may be directly changed to a new process recipe by operating the input/output device of the substrate processing apparatus.

While the embodiment is described by way of an example in which the film is deposited on the wafers 200, the above-described technique is not limited thereto. For example, the above-described technique may be applied to the processes such as an oxidation process, diffusion process, an annealing process and an etching process of the film formed on the wafers 200.

The above-described technique is not limited to the substrate processing apparatus according to the embodiment configured to process semiconductor wafer. The above-described technique may also be applied to an apparatus such as an LCD (Liquid Crystal Display) manufacturing apparatus configured to process glass substrate.

According to the technique described herein, the effect of the substrate retainer on the substrate processing is reduced while maintaining the strength of substrate retainer.

What is claimed is:

1. A substrate retainer configured to support a plurality of substrates in horizontal orientation with an interval therebetween, the substrate retainer comprising:
main support columns; and
auxiliary support columns,
wherein: each of the main support columns is provided with a substrate support member configured to support a substrate; a diameter of each of the auxiliary support columns is larger than a diameter of each of the main support columns and smaller than a length of the substrate support member; a distance between an edge of the substrate and each of the auxiliary support columns is shorter than a distance between the edge of the substrate and each of the main support columns; and all of the auxiliary support columns are not in contact with the substrate.

2. The substrate retainer of claim 1, wherein the substrate support member is provided only at each of the main support columns exclusive of the auxiliary support columns.

3. The substrate retainer of claim 1, wherein the length of the substrate support member ranges from 20 mm to 30 mm.

4. The substrate retainer of claim 1, wherein the main support columns includes a reference column and two main support columns provided along a circumference of a semicircle, the reference column being provided in-line with a charging/discharging direction of the substrate and the two main support columns being provided symmetrically about the reference column at both sides of the reference column.

5. The substrate retainer of claim 4, wherein the auxiliary support columns are provided between the reference column and first one of the two main support columns and the reference column and second one of the two main support columns.

6. The substrate retainer of claim 1, wherein number of the auxiliary support columns is greater than number of the main support columns.

7. The substrate retainer of claim 6, wherein the auxiliary support columns have diameters different from one another, and each and every diameter of the auxiliary support columns is lager than the diameter of each of the main support columns.

8. The substrate retainer of claim 1, wherein cross-sections of the main support columns and the auxiliary support columns are circular, semi-circular, elliptical or polygonal.

9. The substrate retainer of claim 1, wherein number of the main support columns is greater than number of the auxiliary support columns.

10. A substrate processing apparatus comprising:
a process chamber wherein a plurality of substrate is processed;
a substrate retainer configured to support the plurality of substrates in horizontal orientation with an interval therebetween, the substrate retainer comprising:
main support columns; and
auxiliary support columns,
wherein: each of the main support columns is provided with a substrate support member configured to support a substrate; a diameter of each of the auxiliary support columns is larger than a diameter of each of the main support columns and smaller than a length of the substrate support member; a distance between an edge of the substrate and each of the auxiliary support columns is shorter than a distance between the edge of the substrate and each of the main support columns; and all of the auxiliary support columns are not in contact with the substrate;
a process gas supply system configured to supply a process gas into the process chamber; and
a controller configured to control the process gas supply system to supply the process gas to the plurality of substrates supported by the substrate retainer in the process chamber to form films on the plurality of substrates.
